(19) United States
(12) Patent Application Publication
(10) Pub. No.: US 2016/0143194 A1
(43) Pub. Date: May 19, 2016

(54) COIL UNIT

(71) Applicant: YAZAKI CORPORATION, Tokyo (JP)

(72) Inventor: You Yanagida, Shizuoka (JP)

(21) Appl. No.: 14/955,213

(22) Filed: Dec. 1, 2015

Related U.S. Application Data
(63) Continuation of application No. PCT/JP2014/067330, filed on Jun. 30, 2014.

(30) Foreign Application Priority Data
Jul. 2, 2013 (JP) 2013-138737

(51) Int. Cl. H05K 9/00; H01F 27/02; H05K 5/03; H01F 38/14

(52) U.S. Cl. CPC H05K 9/0007; H01F 38/14; H01F 27/02; H05K 5/03

(57) ABSTRACT

The objective of the present invention is to provide a coil unit for a primary coil with which the balance between the mechanical function and the electrical function can easily be adjusted. This coil unit is provided with: a bottom plate that makes contact with a road surface; a shock absorber arranged on the upper surface of the bottom plate; a frame accommodated within the shock absorber; a shielding case that accommodates a primary coil and the upper part of which is accommodated within and opens into the frame; a cover that covers the shielding case; and supporting posts that abut against the shielding case and the cover, and support the cover. The bottom plate, the frame, and the cover, which are primarily responsible for mechanical performance, and the shielding case, which is responsible for electrical property, are formed as separate pieces.

### TECHNICAL FIELD

The present invention relates to coil unit for primary coil equipped at power supply-side in contactless power supply system.

### BACKGROUND ART

Conventionally, contactless power supply system for supplying electrical power with motor vehicle such as electrically-powered car, electric vehicle or the like is configured to include a primary coil at power supply-side and a secondary coil at motor vehicle-side. In the contactless power supply system, electrical power is supplied from the power supply-side to the motor vehicle-side. Since the primary coil at the power supply-side is installed on the ground or embedded in the underground, a coil unit accommodating the primary coil is required to possess electrical performance such as transmitting efficiency or the like, as well as mechanical performance such as load bearing property, waterproof property, or the like. An arrangement structure of primary coil described in PTL 1 is proposed for an arranging method of the power supply-side primary coil. The arrangement structure of the primary coil described in PTL 1 is composed of a base portion and a cover member, and is formed to include an accommodating space in which the primary coil, a magnetic core, or the like are accommodated. The cover member and the base portion are formed with resin concrete so as to improve the load bearing property.

### CITATION LIST

### Patent Literatures

PTL 1: JP 2012-89618 A

### SUMMARY OF INVENTION

### Technical Problem

However, since the conventional coil unit disclosed in PTL 1 accommodates the primary coil inside of the cover member and the base portion that are integrally installed, in a case where the cover member and the base portion are formed to have high thicknesses to improve the load bearing property for example, such a problem is caused as that controlling a balance between mechanical performance such as load bearing property or waterproof property, and electrical performance such as electricity transmitting efficiency or electrical magnetic field leakage reduction property, is made difficult.

In view of the problems as described above, the present invention aims to provide a coil unit for primary coil capable of easily controlling a balance between the mechanical performance and the electrical performance.

### Solution to Problem

To solve the objectives, one aspect of the present invention provides a coil unit for accommodating a primary coil disposed at power supply-side in contactless power supply system comprising: a shielding case comprised of a peripheral wall and a bottom wall, and accommodating the primary coil inside of its accommodation space which opens at an upper portion thereof, a frame provided in a manner surrounding the peripheral wall of the shielding case; and a cover supported by the frame and covering the upper portion of the shielding case.

According to the one aspect of the present invention, by forming separately the frame supporting the cover, which is responsible for the mechanical performance such as load bearing property or waterproof property and the shielding case which is responsible for the electrical performance such as electricity transmitting efficiency or electrical magnetic field leakage reduction property, the coil unit can be designed by considering the mechanical performance and the electrical performance individually.

It is preferable that the one aspect of the present invention further includes a bottom plate supporting the frame from below, wherein the bottom plate is formed to include a projection portion externally protruding further than an outer peripheral portion of the frame, wherein a shock absorber is provided along an upper surface of the projection portion and the outer peripheral portion of the frame, and wherein an upper peripheral edge of the shock absorber is located in a vicinity of the cover.

According to such a configuration, since the shock absorber is arranged at the outer peripheral portion of the frame, and the upper peripheral edge of the shock absorber is located in a vicinity of the cover, the loads of the motor vehicle or the like are applied firstly to the shock absorber when the motor vehicle or the like goes aground the coil unit. Thereby, the shock applied onto the frame, the shielding case and the primary coil accommodated thereinside can be reduced.

Further, it is preferable that in the one or the first preferred aspect of the present invention, an inclined surface lowering toward an outside of the coil unit is formed at the upper peripheral edge of the shock absorber.

According to such a configuration, since the shock absorber including the inclined surface lowering toward the outside of the coil unit is arranged, a difference in level between the road surface and the cover is absorbed so that the tires gradually go aground the coil unit when the motor vehicle or the like goes aground the coil unit. Thereby, the shock applied onto the frame, the shielding case and the primary coil accommodated thereinside can be more effectively reduced.

Further, it is preferable that in any one of the one to the second preferred aspect of the present invention, the accommodation space of the shielding case is provided with a supporting post, the supporting post standing in a vertical direction and abutting against the cover and at least one of the bottom plate and the bottom wall of the shielding case, and a chamfer is formed on at least one of an upper edge face and a lower edge face of the supporting post.

According to such a configuration, since the supporting post which supports the cover is formed, when the motor vehicle or the like goes aground the coil, the loads applied on the inner portion of the cover which is not supported by the frame, can be supported by the supporting post. Thereby, the load bearing property of the coil unit can be enhanced. Further, since at least one of the upper and the lower edge faces of the supporting post is beveling processed, damages to the cover, the bottom plate, the bottom wall or the like against which the upper and the lower edge faces of the supporting post abut, can be prevented when loads are applied to the supporting post.

Further, it is preferable that in the third preferred aspect of the present invention, a coil bobbin is provided in the accommodation space of the shielding case, and wherein the supporting post and the coil bobbin are integrally formed with each other or the coil bobbin is provided with a supporting post insertion hole into which the supporting post is inserted.

According to such a configuration, since the supporting post is integrally formed with the coil bobbin, or the supporting post insertion hole is formed through the coil bobbin, the coil bobbin as well as the supporting post can be effectively arranged within the accommodation space of the shielding case. Thereby, the load bearing property of the coil unit can be enhanced.

Incidentally, for the cover in the present invention, resin materials which cause no influence on the transmitting efficiency are used. Further, although for a member such as the frame, the bottom plate, or the like which supports loads provided from the outside, materials which have no shielding property can be preferably used, materials which have lower shielding property than the shielding case, that is, materials which have lower electrical conductivity than the shielding case may be used as well.

### Advantageous Effects of Invention

According to the coil unit of the present invention, by providing separately the frame and the shielding case from each other, the electrical performance by the shielding case and the mechanical performance by the frame can be designed individually. Therefore, as compared to the conventional method such as directly accommodating the primary coil in between the cover member and the base portion, a coil unit in which the mechanical performance and the electrical performance can be controlled in accordance with an environment or an arrangement condition where the coil unit is arranged, can be advantageously provided.

### BRIEF DESCRIPTION OF DRAWINGS

FIG. 1 is an exploded perspective view of a coil unit according to a first embodiment of the present invention.

FIG. 2 is a cross-sectional view of the coil unit.

FIG. 3 is an exploded perspective view of a coil unit according to a second embodiment of the present invention.

FIGS. 4A and 4B are cross-sectional views of the coil unit of FIG. 3.

FIG. 5 is a cross-sectional view of a coil unit according to a variant of the present invention.

### DESCRIPTION OF EMBODIMENTS

### First Embodiment

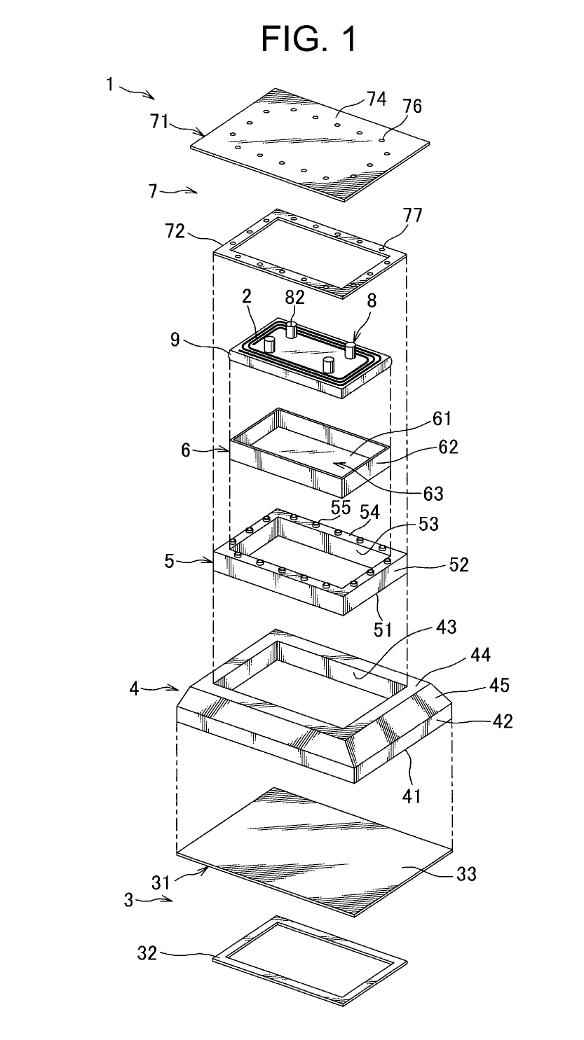

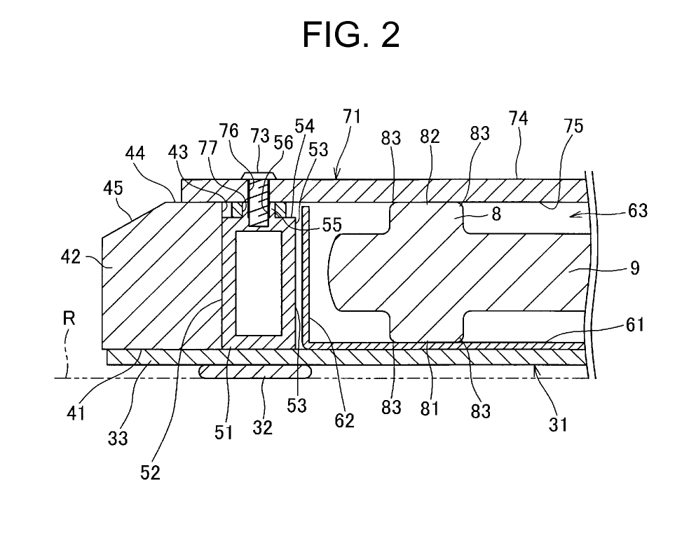

A coil unit according to the first embodiment of the present invention is described with reference to FIGS. 1 and 2. A coil unit 1 of this embodiment is a coil unit for accommodating a primary coil 2 at the power supply-side in a contactless power supply system provided in a motor vehicle or the like, and is installed on a road surface R. A secondary coil not shown is connected to a battery of a motor vehicle or the like. When the motor vehicle or the like is positioned at a predetermined location, the primary coil 2 becomes able to supply electrical power to the secondary coil by utilizing electromagnetic induction.

The coil unit 1 includes the primary coil 2 wound around a coil bobbin 9, a bottom plate 3 directly contacting with the road surface R, a shock absorber 4 arranged on the upper surface of the bottom plate 3, a frame 5 directly contacting with the upper surface of the bottom plate 3 and accommodated within inside of the shock absorber 4, a shielding case 6 accommodating the primary coil 2 and accommodated within the frame 5, a cover 7 covering the shielding case 6, and supporting posts 8 abutting against the shielding case 6 and the cover 7, and supporting the cover 7 from below.

The bottom plate 3 is formed to include a bottom plate body 31 made of a metal material in a plate-like shape, a rubber bottom 32 arranged between the road surface R and the lower surface of the bottom plate body 31, and a projection portion 33 integrally formed with the bottom plate body 31 and externally projecting further than an outer peripheral portion 52 of the frame 5 that will be described later.

The shock absorber 4 is formed in a frame-like shape by using materials such as hard rubber or the like so as to absorb shocks from the outside thereof. The shock absorber 4 is formed to include a lower peripheral edge 41 having an equivalent size to an outer peripheral edge of the projection portion 33 of the bottom plate 3, an outer side surface 42 standing from the lower peripheral edge 41, an inner side surface 43 standing from the lower peripheral edge 41 and opposing to the outer peripheral portion 52 of the frame 5 which will be described later, an upper peripheral edge 44 positioned in a vicinity of a cover body 71 and an inclined surface 45 provided at the upper peripheral edge 44 and lowering toward the outside thereof

The frame 5 is formed in a frame-like shape by using a hollow member made of stainless steel or the like having lower electrical conductivity property than the shielding case 6 which will be described later. The frame 5 is formed to include a lower surface 51 abutting against the bottom plate body 31, the outer peripheral portion 52 standing from the lower surface 51, an inner peripheral portion 53 standing from the lower surface 51 and opposing to a peripheral wall 62 of the shielding case 6 that will be described later, an upper surface 54 connecting the upper end of the outer peripheral portion 52 and the upper end of the inner peripheral portion 53, and fixing projections 55 provided along the entire periphery of the upper surface 54. The fixing projections 55 is provided with a bolt hole 56 for affixing the cover 7 with bolts

The shielding case 6 is a member which is responsible for electrical performance such as electrical transmitting efficiency, electromagnetic field leakage reduction property or the like. The shielding case 6 is formed in a box-like shape which opens upward by using materials having high electrical conductivity such as copper alloy, aluminum alloy or the like. The shielding case 6 is comprised of a bottom wall 61 abutting against the bottom plate body 31, the peripheral wall 62 standing from the outer periphery of the bottom wall 61 and opposing to the inner peripheral portion 53 of the frame 5 and an accommodation space 63 accommodating the primary coil 2 within the bottom wall 61 and the peripheral wall 62.

The cover 7 is formed to include the cover body 71 made of a plate-like member, a frame-like shaped gasket 72 arranged between a lower side face 75 of the cover body 71 and the upper surface 54 of the frame 5, and an affixing bolt 73. The gasket 72 is made of materials such as rubber or the like which have shock-absorbing property. The cover body 71 is provided with affixing holes 76 for inserting the affixing bolt 73 thereinto from an upper side surface 74 side of the cover body 71. The gasket 72 is provided with the insertion holes 77 for inserting the fixing projections 55 provided on the upper surface 54 of the frame 5 thereinto.

The supporting post 8 is integrally formed with the coil bobbin 9, a lower edge face 81 of the supporting post 8 is in contact with the upper surface of the bottom wall 61 in the shielding case 6, and the upper peripheral edge face 82 is in contact with the lower side face 75 of the cover body 71. In the outer periphery of the upper and lower edge faces 81, 82 of the supporting post 8, there is formed a chamfer 83 a beveling processed. Thus, when the coil bobbin 9 is accommodated into the accommodation space 63 of the shielding case 6, the chamfer 83 is prevented from abutting against the lower side face 75 of the cover body 71 and the upper surface of the bottom wall 61 in the shielding case 6.

Next, an example of installing process of the coil unit 1 is described. As for the installing process of the coil unit 1, it is not limited to those that will be described hereinafter, the order of the processes as described below may be properly alternated in so far as the coil unit 1 shown in FIGS. 1 and 2 is configured after the installment thereof.

First, the rubber bottom 32 is placed on the road surface R and the bottom plate body 31 is installed on the rubber bottom 32. Next, the shock absorber 4 is disposed so as to coincide with the outer periphery of the projection portion 33 of the bottom plate 3, and the frame 5 is arranged at the inside of the shock absorber 4. Further, the shielding case 6 accommodating the coil bobbin 9 around which the primary coil 2 is wound, is arranged in the inside of the frame 5. In Final, the fixing projections 55 are inserted into the insertion holes 77 of the gasket 72, and the affixing bolt 73 is screwed into the bolt hole 56 from the upper surface 74 side of the cover body 71 through the affixing hole 76 such that the cover body 71 is affixed to the frame 5, resulting in the completion of the installment of the coil unit 1. Incidentally, in this embodiment, although the frame 5, the cover 7, and the gasket 72 are affixed by bolts, they may be affixed by other measures.

Through the processes as above described, in the coil unit 1, there are accommodated the shock absorber 4, the frame 5, the shielding case 6, and the coil bobbin 9 around which the primary coil 2 is wound, in the order from the outside toward the accommodation space 63 in the shielding case 6.

Next, a method by which loads provided from the outside are supported in the coil unit 1 is described. When the motor vehicle or the like goes aground the coil unit 1, since the motor vehicle or the like firstly goes aground the inclined surface 45 of the shock absorber 4, being located at the outermost part in the coil unit 1, loads such as the motor vehicle or the like are supported by both the shock absorber 4 and the bottom plate 3 against which the lower peripheral edge 41 of the shock absorber 4 abuts. Further, when the motor vehicle or the like goes aground the cover 7, the loads such as the motor vehicle or the like are supported by the cover 7, the frame 5, and the bottom plate 3. Also, when the motor vehicle or the like goes aground the inner portion of the cover 7 which is not supported by the frame 5, the loads such as the motor vehicle or the like are supported also by the supporting post 8.

Hence, in the coil unit 1, the bottom plate 3, the shock absorber 4, the frame 5, and the cover 7 are primarily responsible for the load bearing property, and in the inner portion of the cover 7, which is not supported by the frame 5, the supporting post 8 is supporting the loads as well.

Further, since the gasket 72 is arranged between the lower side face 75 of the cover body 71 and the upper surface 54 of the frame 5, the coil unit 1 shows a water-stopping property with respect to the shielding case 6 and the primary coil 2 accommodated within the space that is more inside of the coil unit 1 than the frame 5.

According to this embodiment, by forming separately the bottom plate 3, the frame 5, and the cover 7 which are primarily responsible for mechanical performance such as load bearing property or waterproof property from the shielding case 6 which is responsible for electrical performance such as electrical transmitting efficiency or electromagnetic field leakage reduction property, a design can be created individually by considering mechanical performance and electrical performance individually. Therefore, a balance between mechanical performance and electrical performance can be easily controlled.

Further, since the shock absorber 4 is arranged along the projection portion 33 of the bottom plate 3 and the outer peripheral portion 52 of the frame 5, and the upper peripheral edge 44 of the shock absorber 4 is located in a vicinity of the cover 7, when the motor vehicle or the like goes aground the coil unit 1, the loads of the motor vehicle or the like are applied firstly onto the shock absorber 4. Thereby, the shock applied onto the frame 5, the shielding case 6 accommodated thereinside, the primary coil 2, and the coil bobbin 9, can be reduced.

Further, since at the upper peripheral edge 44 of the inclined surface 45, there is formed the inclined surface 45 lowering toward the outside of the coil unit 1, when the motor vehicle or the like goes aground the coil unit 1, a difference in level between the road surface R and the cover 7 is absorbed, and tires of the motor vehicle or the like gradually go aground the coil unit 1. Thereby, the shock applied onto the frame 5, the shielding case 6 accommodated thereinside, the primary coil 2, and the coil bobbin 9 can be more effectively reduced.

Further, since the supporting post 8 which supports the cover 7 from below is provided between the bottom wall 61 of the shielding case 6 and the lower side face 75 of the cover body 71, when the motor vehicle or the like goes aground the coil unit 1, the loads applied on the inner portion of the cover 7 which are not supported by the frame 5 can be supported also by the supporting post 8. Thereby, the load bearing property of the coil unit 1 can be enhanced.

Further, since the chamfer 83 beveling processed is provided on the upper and lower edge faces 81, 82 of the supporting post 8, when the loads are applied to the supporting post 8, damages provided to the cover 7 against which the upper and lower edge faces 81, 82 of the supporting post 8 abut, and damages provided to the bottom wall 61 of the shielding case 6, can be prevented.

Further, since the supporting post 8 is integrally formed with the coil bobbin 9, the supporting post 8 can be efficiently arranged in the accommodation space 63 of the shielding case 6. Thereby, the load bearing property of the coil unit 1 can further be enhanced.

### Second Embodiment

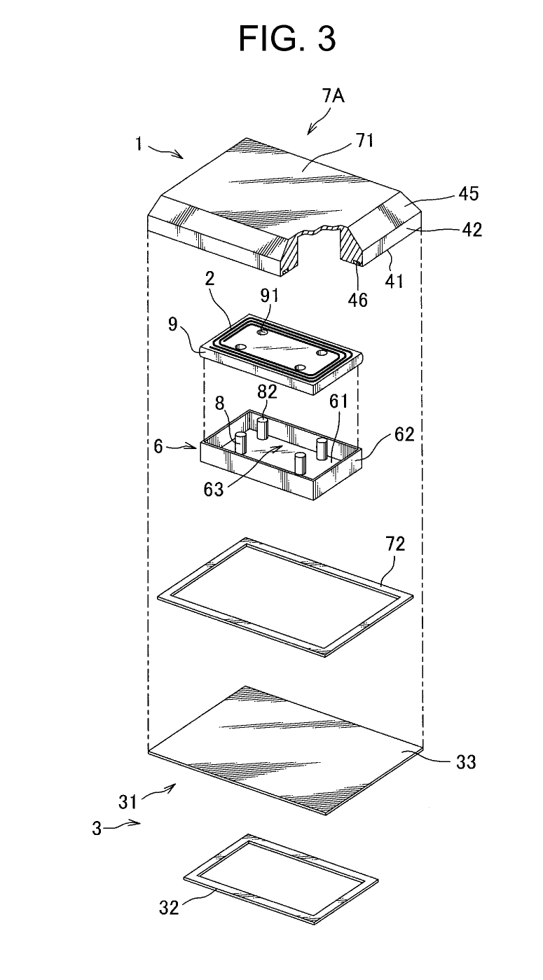

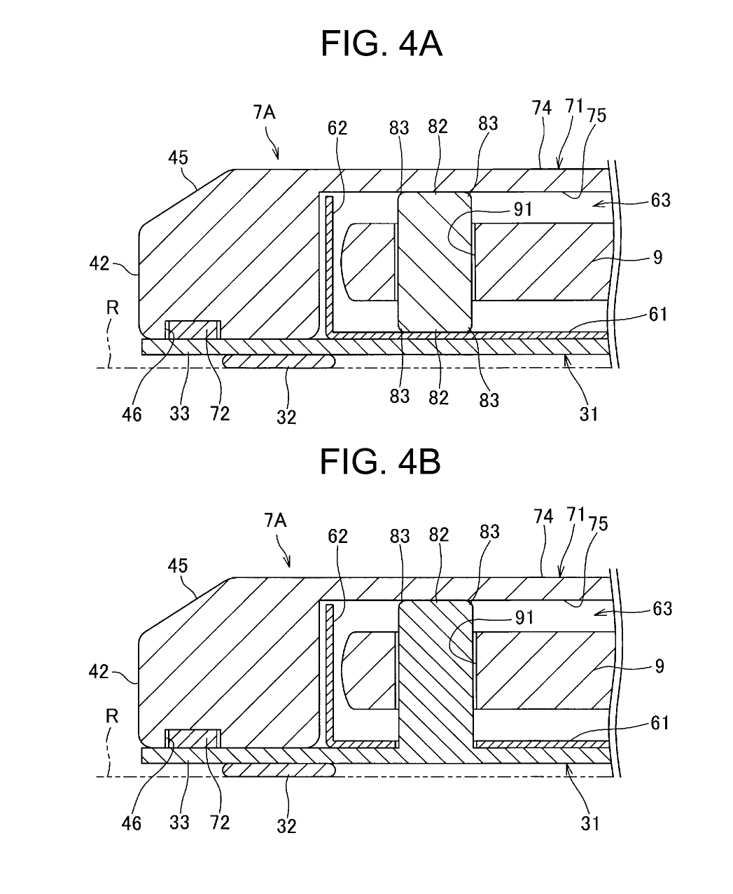

A coil unit according to the second embodiment of the present invention is described with reference to FIGS. 3, 4A and 4B. FIG. 3 is an exploded perspective view of a coil unit according to a second embodiment of the present invention, and shows a partial sectional view of a cover 7A that will be described later. The coil unit 1 includes a bottom plate 3 that has almost the same shape as that of the first embodiment.

In this embodiment, the cover 7A is formed as a component integrally composed of the shock absorber 4, the frame 5, and the cover 7 of the first embodiment. In the lower peripheral edge 41, there is provided a groove 46 in which the gasket 72 arranged between the cover 7A and the bottom plate 3, is fitted.

Further, the supporting post 8 standing from the bottom wall 61 of the shielding case 6 supports the cover 7A from below, through the coil bobbin 9, there are formed supporting post insertion holes 91 into which the supporting posts 8 are inserted.

According to this embodiment, since the supporting post 8 is standing from the bottom wall 61 of the shielding case 6 and is inserted into the supporting post insertion hole 91 formed through the coil bobbin 9, the supporting post 8 can be effectively arranged in the accommodation space 63 of the shielding case 6. Thereby, the load bearing property of the coil unit 1 can be enhanced.

Further, since the cover 7A is integrally formed with the shock absorber 4 and the frame 5, and in the shielding case 6, a portion lower than the upper surface opening portion thereof can be covered by a single member, the waterproof property the coil unit 1 can be enhanced.

Further, in this embodiment, as shown in FIG. 4A, the supporting post 8 is supported by the bottom wall 61 of the shielding case 6. As shown in FIG. 4B, the supporting post 8 may be integrally formed with the bottom plate body 31 in so far as the supporting post 8 is capable of supporting the cover 7A. On this occasion, the supporting post insertion hole 64 is formed through the shielding case 6.

Incidentally, in each embodiment as described above, the shielding case 6 is made of copper alloy or aluminum alloy having high electrical conductivity property, other materials having electrical conductivity property can be used in so far as the shielding case 6 has a shielding property. As for members such as the bottom plate 3, the frame 5, the supporting post 8 or the like which are responsible for the load bearing property, a resin material or the like having no electrical conductivity, or a metallic material such as stainless steel or the like having lower electrical conductivity property than materials used for the shielding case 6 may be used. Although the shock absorber 4 is made of a hard rubber, any materials can be used in so far as the materials are able to reduce shocks made by the motor vehicle or the like.

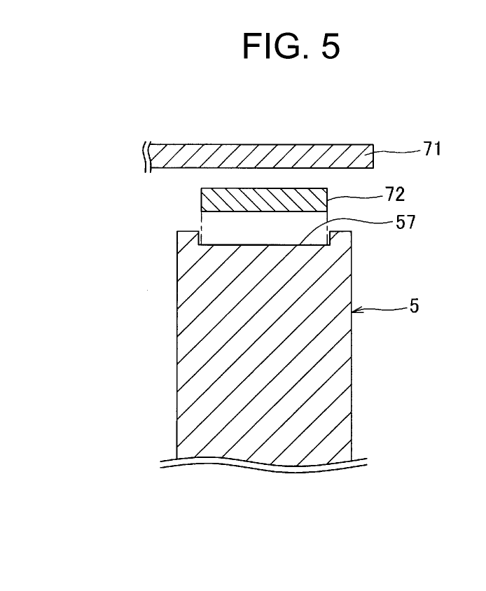

Further, in the first embodiment, although the gasket 72 of the cover is provided with insertion holes 77 into which the fixing projections 55 of the frame are inserted, and the gasket 72 is arranged between the cover body 71 and the frame 5, the gasket 72 can be fitted into the groove 57 provided at the lower side face 75 of the cover body 71 and the upper surface 54 of the frame 5 as shown in FIG. 5.

Further, the coil unit 1 is installed on the road surface R, the coil unit 1 may be embedded in the underground in so far as electricity can be supplied to the secondary coil mounted in the motor vehicle or the like.

Although other optimum configurations or methods for implementing the present invention are described in the above descriptions, the present invention is not limited thereto. That is, the present invention is primarily shown and described in specific drawings in regard to particular embodiments, the skilled in the art can variably modify the above described embodiments in shapes, materials, numbers/amounts, or other detailed configurations.

Therefore, the descriptions in which shapes or materials are disclosed as above is the exemplifying descriptions for facilitating the understanding of the present invention, the present invention is not limited thereto. Hence, the present invention includes descriptions in which the members are described in the names of partial limitation such as shapes or materials thereof or in the names of not having all the limitations thereof.

### REFERENCE SIGNS LIST

1 coil unit
2 primary coil
3 bottom plate
33 projection portion
4 shock absorber
44 upper peripheral edge
45 inclined surface
5 frame
52 outer peripheral portion
6 shielding case
61 bottom wall
62 peripheral wall 63 accommodation space
7, 7A cover
8 supporting post
81 lower edge face
82 upper peripheral edge face
83 chamfer
9 coil bobbin
91 supporting post insertion hole

1. A coil unit for accommodating a primary coil disposed at power supply-side in contactless power supply system comprising:
a shielding case comprised of a peripheral wall and a bottom wall, and accommodating the primary coil inside of its accommodation space which opens at an upper portion thereof;
a frame provided in a manner surrounding the peripheral wall of the shielding case; and
a cover supported by the frame and covering the upper portion of the shielding case.

2. The coil unit according to claim 1, further comprising a bottom plate supporting the frame from below, wherein
the bottom plate is formed to include a projection portion externally protruding further than an outer peripheral portion of the frame, wherein
a shock absorber is provided along an upper surface of the projection portion and the outer peripheral portion of the frame, and wherein
an upper peripheral edge of the shock absorber is located in a vicinity of the cover.

3. The coil unit according to claim 2, wherein
an inclined surface lowering toward an outside of the coil unit is formed at the upper peripheral edge of the shock absorber.

4. The coil unit according to claim 1, wherein
the accommodation space of the shielding case is provided with a supporting post, the supporting post standing in a vertical direction and abutting against the cover and at least one of the bottom plate and the bottom wall of the shielding case, and a chamfer is formed on at least one of an upper edge face and a lower edge face of the supporting post.

5. The coil unit according to claim 2, wherein
the accommodation space of the shielding case is provided with a supporting post, the supporting post standing in a vertical direction and abutting against the cover and at least one of the bottom plate and the bottom wall of the shielding case, and a chamfer is formed on at least one of an upper edge face and a lower edge face of the supporting post.

6. The coil unit according to claim 3, wherein
the accommodation space of the shielding case is provided with a supporting post, the supporting post standing in a vertical direction and abutting against the cover and at least one of the bottom plate and the bottom wall of the shielding case, and a chamfer is formed on at least one of an upper edge face and a lower edge face of the supporting post.

7. The coil unit according to claim 4, wherein
a coil bobbin is provided in the accommodation space of the shielding case, and wherein
the supporting post and the coil bobbin are integrally formed with each other or the coil bobbin is provided with a supporting post insertion hole into which the supporting post is inserted.

8. The coil unit according to claim 5, wherein
a coil bobbin is provided in the accommodation space of the shielding case, and wherein
the supporting post and the coil bobbin are integrally formed with each other or the coil bobbin is provided with a supporting post insertion hole into which the supporting post is inserted.

9. The coil unit according to claim 6, wherein
a coil bobbin is provided in the accommodation space of the shielding case, and wherein
the supporting post and the coil bobbin are integrally formed with each other or the coil bobbin is provided with a supporting post insertion hole into which the supporting post is inserted.
